(19) United States
(12) Patent Application Publication
(10) Pub. No.: US 2020/0058813 A1
(43) Pub. Date: Feb. 20, 2020

(54) CONDUCTIVE FILM, PHOTOVOLTAIC CELL UNIT, AND PHOTOVOLTAIC CELL MODULE

(71) Applicant: PERM TOP CO., LTD, NEW TAIPEI CITY (TW)

(72) Inventors: Po-Pin CHEN, NEW TAIPEI CITY (TW); Ching-Chuan LAI, NEW TAIPEI CITY (TW)

(21) Appl. No.: 16/102,730

(22) Filed: Aug. 14, 2018

(51) Int. Cl. H01L 31/05; H01L 31/02; H01L 31/054; B32B 17/10; B32B 27/08

(52) U.S. Cl. CPC H01L 31/0504; H01L 31/02013; B32B 2457/12; B32B 17/10678; B32B 27/08; H01L 31/054

(57) ABSTRACT

A conductive film, a photovoltaic cell unit, and a photovoltaic cell module are disclosed. The conductive film adapted to electrically connect two adjacent photovoltaic cells in series includes at least one wire, a light transmissive layer, and a light transmissive resin layer, the light transmissive layer covers the wire, and the light transmissive resin layer is at least disposed between the wire and the light transmissive layer.

### BACKGROUND

### Technical Field

The present disclosure relates to a conductive film, more particularly, to a conduct film adapted to electrically connect two adjacent photovoltaic cells of a photovoltaic cell unit in series.

### Description of Related Art

FIG. 1 is a cross sectional view of a related art photovoltaic cell module 1. In FIG. 1, the photovoltaic cell module 1 includes a light transmissive plate 12 having a light-previous property, a back plate 14 opposite to the light transmissive plate 12, and a photovoltaic cell unit 16 located between the light transmissive plate 12 and the back plate 14 and includes a plurality of photovoltaic cells 162 and a plurality of cell ribbons 164. Each photovoltaic cell 162 has a light receiving surface 1620 and a non-light receiving surface 1622.

The cell ribbons 162 are made of copper, indium or an alloy thereof. Specifically, each cell ribbon 164 includes a first portion 1640, a second portion 1642, and a third portion 1644. The first portion 1640 of the cell ribbon 164 is disposed on the light receiving surface 1620 of one of the photovoltaic cells 162 and electrically connected to the front surface electrode pattern (not shown) of the one of the photovoltaic cell 162; the third portion 1644 of the cell ribbon 164 is disposed on the non-light receiving surface 1622 of the other photovoltaic cell 162 and electrically connected to ribbon 164 is connected to the first portion 1640 and the third portion 1644. In short, the cell ribbon 164 is used to electrically connect two adjacent photovoltaic cells in series.

The cell ribbons 164 are non-flexible since they are made of cooper, indium or an alloy thereof, thus the cell ribbons 164 may be separated from the photovoltaic cells 164 by collision or extrusion during transportation or assembly and the photovoltaic cells may break during the conductive film 34 is warpage under high temperature or UV exposure.

### SUMMARY

In general, one innovation aspect of the subject matter described in this specification can be embodied in a conductive film adapted to electrically connect two adjacent photovoltaic cells in series including one or more wires; a light transmissive layer covering the one or more wires; and a light transmissive resin layer at least disposed between the one or more wires and the light transmissive layer for combining the one or more wires and the light transmissive layer.

Another innovative aspect of the subject matter described in this specification can be embodied in a photovoltaic cell unit including a plurality of photovoltaic cells and the conductive film mentioned above. Each photovoltaic cell unit has a light receiving surface and a non-light receiving surface. A first end of the conductive film is disposed on the light receiving surface of one of the photovoltaic cell, so that the one or more wires at the first end are in contact with one or more electrodes disposed on the light-receiving surface of the photovoltaic cell, a second end of the conductive film passes the non-light receiving surface of the other photovoltaic cell and then bends inward, so that the one or more wires at the second end are in contact with one or more electrodes disposed on the non-light receiving surface of the other photovoltaic cell.

Another innovative aspect of the subject matter described in this specification can be embodied in a photovoltaic cell unit includes a plurality of photovoltaic cells and the conductive film mentioned above. Each photovoltaic cell has a light receiving surface and a non-light receiving surface. A first end of conductive film is disposed on the light receiving surface of one of the photovoltaic cell and the one or more wires is in contact with one or more electrodes disposed on the light receiving surface of the photovoltaic cell, and the light transmissive resin layer at the first end of the conductive film is in contact with the light receiving surface of the photovoltaic cell, a second end of the conductive film passes through the non-light receiving surface of the other photovoltaic cell and then bends inward, so that the one or more wires are in contact with one or more electrodes disposed on the non-light receiving surface of the other photovoltaic cell, and the light transmissive resin at the second end of the conductive film is in contact with the non-light receiving surface of the other photovoltaic cell.

Another innovative aspect of the subject matter described in this specification can be embodied in a photovoltaic cell module including a light transmissive plate, a cover plate opposite to the light transmissive plate, and a plurality of photovoltaic cells mentioned above located between the light transmissive plate and the cover plate.

### BRIEF DESCRIPTION OF DRAWING

The present disclosure can be more fully understood by reading the following detailed description of the embodiment, with reference made to the accompanying drawings as follows:

FIG. 1 is a cross-sectional view schematically illustrating a related art photovoltaic cell;

FIG. 2 is a top view of a photovoltaic cell unit according to an embodiment of the present disclosure;

FIG. 3 is a cross-sectional view of the photovoltaic cell unit according to the embodiment of the present disclosure;

FIG. 4A is a cross-sectional view of the photovoltaic cell unit according to the embodiment of the present disclosure;

FIG. 4B is a cross-sectional view of the photovoltaic cell unit according to another embodiment of the present disclosure;

FIG. 5 is a cross-sectional view of a photovoltaic cell module according to the embodiment of the present disclosure; and

FIG. 6 is a top view of the photovoltaic cell module according to the embodiment of the present disclosure.

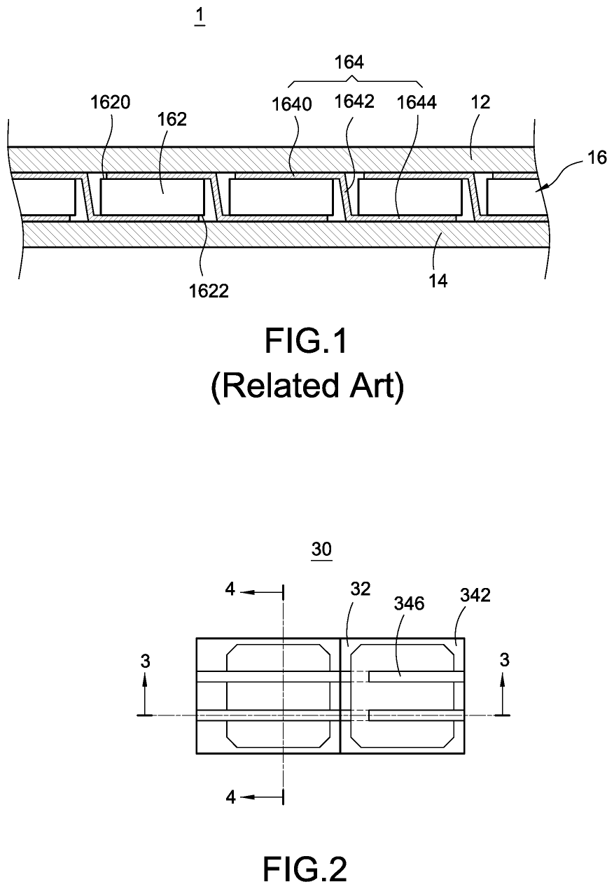

### DETAILED DESCRIPTION

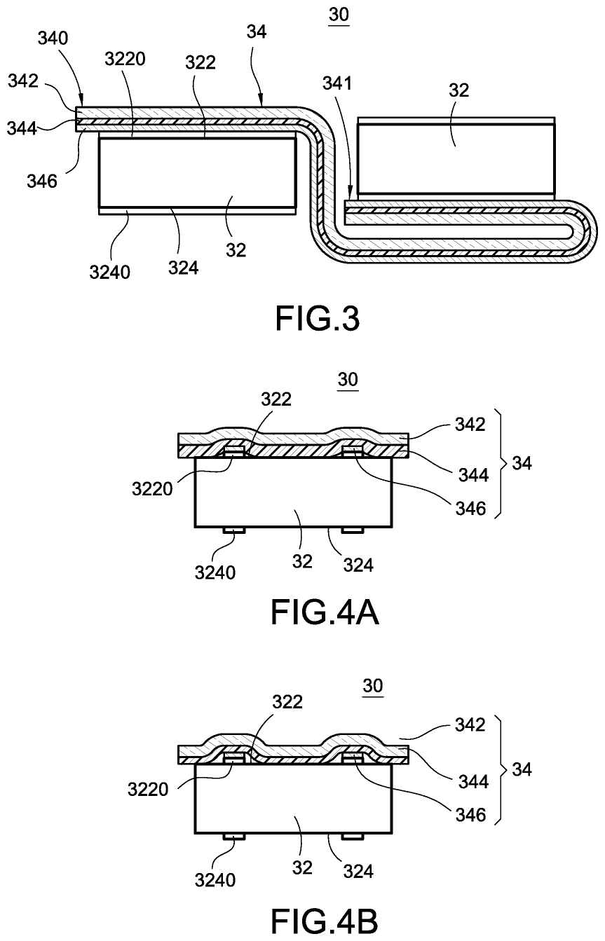

FIG. 2 is a top view of a photovoltaic cell unit according to an embodiment of the present disclosure, and FIG. 3-4B are cross-sectional views of the photovoltaic cell unit according to the embodiment of the present disclosure. In FIG. 2-4B, the photovoltaic cell unit 30 includes (at least) two photovoltaic cells 32 arranged along a predetermined direction, and a conductive film 34. Each photovoltaic cell unit 30 has a light receiving surface 322 and a non-light receiving surface 324 opposite to the light receiving surface 322.

The conductive film 34 is adapted to electrically connect two adjacent photovoltaic cells 32 in series and includes a light transmissive layer 342, a light transmissive resin layer 344 stacked on the light transmissive layer 342, and at least one wires 346 stacked on and embedded in the light transmissive resin layer 344. The light transmissive layer 342 is flexible and made of light transmissive polymer having a high heat-resistance to yellowing under ultraviolet (UV) light or heat exposing. For example, the light transmissive layer 342 may be selected from the group of polyethylene terephthalate (PET), polycarbonate (PC), polymethacrylate (PMMA), and combinations thereof. The light transmissive resin layer 344 may be acrylate or silicone.

The conductive film 34 may include one or more wires 346. When the conductive film 34 includes more than two wires 346, the one or more wires 346 are arranged in parallel. Specifically, as shown in FIG. 2, the wires 346 extends along the predetermined direction, so that the lengthwise direction of the wires 346 is parallel to the predetermined direction; the wires 346 are arranged in parallel along the widthwise direction thereof. An amount of the wire(s) 346 is equal to an amount of light-receiving surface electrode(s) 3220 or the non-light-receiving surface electrode(s) 3240; in general, an amount of the light-receiving surface electrode(s) is equal to the non-light-receiving surface electrode(s). In this embodiment, the conductive film 34 includes, for example, two wires 346, and a distance between the wires 346 is identical or substantially similar to a distance between the light-receiving surface electrodes 3220 (or the non-light-receiving surface electrodes 3240) of each photovoltaic cell 32.

As described above, during the conductive film 34 is used for electrically connecting two adjacent photovoltaic cells 32, the amount of the wire(s) 346 of the conductive film 34 is equal to the amount of the light-receiving surface electrode(s) 3220 or the non-light-receiving surface electrode(s) 3240. However, during the conductive film 34 is used for electrically connecting a plurality of photovoltaic cell array constituted of two or more photovoltaic cells 32 in series connection in parallel, the amount of the wires 346 disposed on conductive film 34 is equal to the amount of the light-receiving surface electrodes 3220 or the non-light-receiving surface electrodes 3240 of the photovoltaic cells 32 arranged along a direction perpendicular to the predetermined direction (i.e., in parallel to the widthwise direction of the wires 346). For example, for a 2×2 photovoltaic cell matric, and each photovoltaic cell 32 has two light-receiving surface electrodes 3220 and/or two non-light-receiving surface electrodes 3240, there may be 4 wires 346 arranged in parallel along the widthwise direction thereof. The conductive wires 346 may be made of single-layered or multi-layered metal, where multi-layered metal is, for example, tin-plated copper. The wires 346 made of multi-layered metal may have higher durability against that made of single-layered metal.

The light transmissive resin layer 344 is at least disposed between the light transmissive layer 342 and the wires 346. Specifically, the light transmissive resin layer 344 may be disposed on the portion of the light transmissive layer 342 on which the one or more wires 342 are disposed for combining the light transmissive layer 342 and the one or more wires 346, as shown in FIG. 3. The light transmissive resin layer 344 may be filled up with light transmissive layer 342, so that the light transmissive resin layer 344 may further be used for combining the light transmissive layer 342 and the photovoltaic cells 32 on which the one or more wires 342 are not disposed, as shown in FIG. 4A and FIG. 4B for preventing the one or more wires 342 from moving during transportation. In FIG. 4A, a thickness of the light transmissive resin layer 344 at the region where the one or more wires are not disposed is higher than that the one or more wires are disposed; in the other words, the one or more wires 346 shown in FIG. 4A are embedded within the light transmissive resin layer 344. In FIG. 4B, the light transmissive resin layer 344 has a uniform thickness; namely, the thickness of the light transmissive resin layer 344 shown in FIG. 4B is a constant. In this condition, the one or more wires 346 are disposed over the light transmissive resin layer 344. In order to be in contact with the photovoltaic cells 32, the bending phenomenon of the conductive film 34 near a junction of the light transmissive resin 344 and the wires 346 will bend with large curvature in respect to which shown in FIG. 4A.

With referring again to the FIG. 3; during the assembly process, the one or more wires 346 at a first end 340 of the conductive film 34 are firstly aligned and in contact with the one or more light-receiving electrodes 3220 of a first photovoltaic cell 32, and then the light transmissive resin 344 where the one or more wires 346 are not disposed is in contact with the light receiving surface 322 of the first photovoltaic cells 30 for combining the conductive film 34 and the first photovoltaic cell 32. Since the conductive film 34 is flexible, a second end 341 of the conductive film 34 may bend downward and pass the non-light receiving surface 324 of a second photovoltaic cell 32; thereafter, the second end 341 of the conductive film 34 bends inward, so that the one or more wires 346 at the second end 341 may be align and in contact with the one or more non-light-receiving surface electrodes 3240 of the second photovoltaic 30. After that, the light transmissive resin 344 where the one or more wires 346 are not disposed is in contact with the light receiving surface 322 of the second photovoltaic cells 30 for combining the conductive film 34 and the second photovoltaic cell 32. As such, two photovoltaic cells (i.e., the first and second photovoltaic cells) 32 are electrically connected in series.

Furthermore, the one or more wires 346 at the first end 340 of the other conductive film 34 may be aligned and in contact with the one or more light-receiving electrodes 3220 of the second photovoltaic 32, and then the light transmissive resin 344 where the one or more wires 346 are not disposed is in contact with the light receiving surface 322 of the second photovoltaic cells 32 for combining the other conductive film 34 and the second photovoltaic cell 32. The second end 341 of the other conductive film 34 may then bend downward and pass the non-light receiving surface 324 of a third photovoltaic cell 32; thereafter, the second end 341 of the other conductive film 34 bends inward, so that the one or more wires 346 at the second end 341 of the other conductive film 34 may be align and in contact with the one or more non-light-receiving surface electrodes 3240 of the third photovoltaic 32. After that, the light transmissive resin layer 344 where the one or more wires 346 are not disposed is in contact with the light receiving surface 322 of the third photovoltaic cells 30 for combining the other conductive film 34 and the third photovoltaic cell 32. As such, three photovoltaic cells (i.e., the first to third photovoltaic cells) 32 are electrically connected in series.

By repeatedly connecting the wire(s) 346 at the first end 340 of the conductive film 34 to the light-receiving surface electrode(s) 3220 of one of the photovoltaic cell 32, bending the second end 341 of the conductive film 34 downward between two adjacent photovoltaic cells 32 and passing the non-light-receiving surface 324 of the other photovoltaic cell 32, and bending the second end 341 of the conductive film 34 inward for connecting the wire(s) 346 at the second end 341 of the conductive film 34 to the non-light-receiving surface electrode(s) 3240, multiple photovoltaic cells 32 may be electrically connected in series.

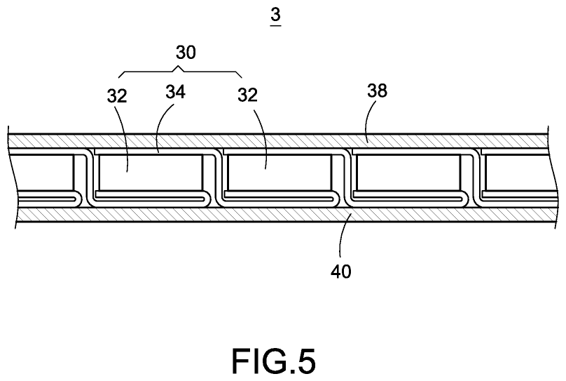

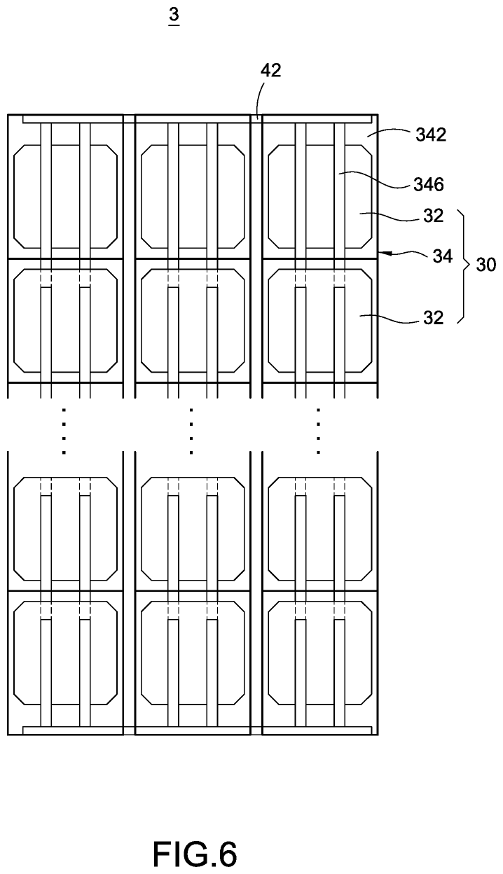

As shown in FIG. 5, the photovoltaic cells 32 in series connection, a light transmissive plate 38, and a cover plate 40 may collectively constitute the photovoltaic cell module 3; the cover plate 40 is opposite to the light transmissive plate 38, and photovoltaic cells 32 are located between the light transmissive plate 38 and the cover plate 40. The light transmissive plate 38 and the cover plate 40 may be, for example, strengthened glasses; however, the cover plate 40 may be copper plate for improving heat dissipation capability. The photovoltaic cell module 3 may include one or more photovoltaic cell arrays. The photovoltaic cell module 3 may further include a bus 42 for electrically connecting the photovoltaic cell arrays in parallel.

To sum up, the light transmissive layer 342 and the light transmissive resin layer 344 are made of materials which the thermal conductively is at least higher than 90 degrees Celsius, which capable of decreasing warpage of the conductive film 34 under heat environment. In addition, the conductive film 34 of the present disclosure is flexible, it is possible to prevent the conductive film 34 from being separated from the photovoltaic cells 32 by collision or extrusion during transportation or assembly, and the photovoltaic cells 32 can be prevent from breaking as well during the conductive film 34 is warpage.

Although the present disclosure has been described with reference to the foregoing preferred embodiment, it will be understood that the disclosure is not limited to the details thereof. Various equivalent variations and modifications can still occur to those skilled in this art in view of the teachings of the present disclosure. Thus, all such variations and equivalent modifications are also embraced within the scope of the disclosure as defined in the appended claims.

What is claimed is:

1. A conductive film adapted to electrically connect two adjacent photovoltaic cells in series, the conductive film comprising:
one or more wires;
a light transmissive layer covering the one or more wires; and
a light transmissive resin layer at least disposed between the one or more wires and the light transmissive layer for combining the one or more wires and the light transmissive layer.

2. The conductive film of claim 1, wherein the light transmissive layer film is filled up with the light transmissive layer.

3. The conductive film of claim 1, wherein the one or more wires are made of metal.

4. The conductive film of claim 1, wherein the light transmissive layer is selected from the group of polyethylene terephthalate (PET), polycarbonate (PC), polymethacrylate (PMMA), and combinations thereof

5. The conductive film of claim 1, wherein the light transmissive layer film is acrylate or silicone.

6. A photovoltaic cell unit, comprising:
two photovoltaic cells, wherein each of the photovoltaic cell has a light receiving surface and a non-light receiving surface; and
the conductive film of claim 1, wherein a first end of the conductive film is disposed on the light receiving surface of one of the photovoltaic cell, so that the one or more wires at the first end are in contact with one or more electrodes disposed on the light-receiving surface of the photovoltaic cell, a second end of the conductive film passes the non-light receiving surface of the other photovoltaic cell and then bends inward, so that the one or more wires at the second end are in contact with one or more electrodes disposed on the non-light receiving surface of the other photovoltaic cell.

7. A photovoltaic cell module, comprising:
a light transmissive plate;
a cover plate opposite to the light transmissive plate; and
a plurality of photovoltaic cells of claim 6 located between the light transmissive plate and the cover plate.

8. A photovoltaic cell unit, comprising:
a plurality of photovoltaic cells, wherein each photovoltaic cell has a light receiving surface and a non-light receiving surface; and
the conductive film of claim 2, wherein a first end of conductive film is disposed on the light receiving surface of one of the photovoltaic cell and the one or more wires is in contact with one or more electrodes disposed on the light receiving surface of the photovoltaic cell, and the light transmissive resin layer at the first end of the conductive film is in contact with the light receiving surface of the photovoltaic cell, a second end of the conductive film passes through the non-light receiving surface of the other photovoltaic cell and then bends inward, so that the one or more wires are in contact with one or more electrodes disposed on the non-light receiving surface of the other photovoltaic cell, and the light transmissive resin at the second end of the conductive film is in contact with the non-light receiving surface of the other photovoltaic cell.

9. A photovoltaic cell module, comprising:
a light transmissive plate;
a cover plate opposite to the light transmissive plate; and
a plurality of photovoltaic cells of claim 8 located between the light transmissive plate and the cover plate.

10. The photovoltaic cell module of claim 9, wherein the photovoltaic cell units are electrically connected in series.

11. The photovoltaic cell module of claim 9, wherein the photovoltaic cell units are electrically connected in parallel, and the photovoltaic cell module further comprises a bus used for connecting the photovoltaic cell units.
